(19) United States
(12) Patent Application Publication
(10) Pub. No.: US 2013/0087190 A1
(43) Pub. Date: Apr. 11, 2013

(54) PHOTOVOLTAIC DEVICES AND METHODS OF FORMING THE SAME

(71) Applicants: Sijin Han, Milpitas, CA (US); Fan Yang, Sunnyvale, CA (US)

(72) Inventors: Sijin Han, Milpitas, CA (US); Fan Yang, Sunnyvale, CA (US)

(73) Assignee: QUALCOMM MEMS Technologies, Inc., San Diego, CA (US)

(21) Appl. No.: 13/270,603

(22) Filed: Oct. 11, 2011

(51) Int. Cl. H01L 31/0376; H01L 31/0264; H01L 31/18; H01L 31/0224

(52) U.S. Cl. 136/256; 136/252; 136/258; 136/260; 438/87; 257/E31.047

(57) ABSTRACT

This disclosure provides photovoltaic apparatus and methods of forming the same. In one implementation, a photovoltaic device includes an anode contact structure, a cathode contact structure, and an inorganic solar cell disposed between the anode and cathode contact structures. The inorganic solar cell includes a p-type photovoltaic layer, an n-type photovoltaic layer, and one or more minority carrier blocking layers for improving the efficiency of the solar cell by preventing minority carriers within the solar cell from reaching interface recombination surfaces associated with the anode and cathode contact structures.

### TECHNICAL FIELD

This disclosure relates to photovoltaic devices.

### DESCRIPTION OF THE RELATED TECHNOLOGY

For over a century fossil fuels such as coal, oil, and natural gas have provided the main source of energy in the United States. The need for alternative sources of energy is increasing. Fossil fuels are a non-renewable source of energy that is depleting rapidly. The large scale industrialization of developing nations such as India and China has placed a considerable burden on available fossil fuel. In addition, geopolitical issues can quickly affect the supply of such fuel. Global warming is also of greater concern in recent years. A number of factors are thought to contribute to global warming; however, widespread use of fossil fuels is presumed to be a major contributor to global warming. Thus, there is a need to find a renewable and economically viable source of energy that is also environmentally safe. Solar energy is an environmentally safe renewable source of energy that can be converted into other forms of energy such as heat and electricity.

Photovoltaic cells convert optical energy to electrical energy and thus can be used to convert solar energy into electrical power. Photovoltaic cells can be made very thin and modular, and can range in size from about a few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Additionally, photovoltaic cells can be used in a wide range of applications, such as providing power to satellites and other spacecraft, providing electricity to residential and commercial properties, charging automobile batteries, and powering mobile devices, such as smart phones or personal computers.

While photovoltaic devices have the potential to reduce reliance upon hydrocarbon fuels, the widespread use of photovoltaic devices has been hindered by a variety of factors, including energy inefficiency. Accordingly, there is a need for photovoltaic devices having improved efficiency.

### SUMMARY

The systems, methods and devices of the disclosure each have several innovative aspects, no single one of which is solely responsible for the desirable attributes disclosed herein.

One innovative aspect of the subject matter disclosed in this disclosure can be implemented in a photovoltaic device including an anode contact structure, a cathode contact structure, and an inorganic solar cell disposed between the anode and cathode contact structures. The inorganic solar cell includes a p-type photovoltaic layer adjacent the anode contact structure, an n-type photovoltaic layer disposed between the cathode contact structure and the p-type photovoltaic layer, and a hole blocking layer also disposed between the cathode contact structure and the p-type photovoltaic layer. The hole blocking layer provides an energy barrier to holes that is more than an energy barrier provided to electrons.

In some implementations, a boundary between the cathode contact structure and the inorganic solar cell defines a first interface surface, and the hole blocking layer prevents holes in the p-type photovoltaic layer from reaching the first interface surface and permits electrons to cross when the inorganic solar cell is generating current.

In some implementations, the hole blocking layer has a band gap that is about 0.2 eV to about 1.0 eV greater than a band gap of the p-type photovoltaic layer.

Another innovative aspect of the subject matter disclosed in this disclosure can be implemented in a method of forming a thin film solar cell device, the method including providing an anode contact structure, providing an inorganic solar cell adjacent the anode contact structure, and providing a cathode contact structure adjacent the inorganic solar cell on a side of the inorganic solar cell opposite the anode contact structure. Providing the inorganic solar cell includes providing a p-type photovoltaic layer adjacent the anode contact structure, providing an n-type photovoltaic layer between the cathode contact structure and the p-type photovoltaic layer, and providing a hole blocking layer between the cathode contact structure and the p-type photovoltaic layer. The hole blocking layer provides an energy barrier to holes that is more than an energy barrier provided to electrons.

In some implementations, forming the hole blocking layer includes forming the hole blocking layer between the p-type and n-type photovoltaic layers.

Another innovative aspect of the subject matter disclosed in this disclosure can be implemented in a photovoltaic device including an anode contact structure, a cathode contact structure, and an inorganic solar cell disposed between the anode and cathode contact structures. The inorganic solar cell includes a p-type photovoltaic layer adjacent the anode contact structure, an n-type photovoltaic layer disposed between the cathode contact structure and the p-type photovoltaic layer, and a means for blocking holes disposed between the cathode contact structure and the p-type photovoltaic layer. The hole blocking means provides an energy barrier to holes that is more than an energy barrier provided to electrons.

Another innovative aspect of the subject matter disclosed in this disclosure can be implemented in a photovoltaic device including an anode contact structure, a cathode contact structure, and an inorganic solar cell disposed between the anode and cathode contact structures. The inorganic solar cell includes an n-type photovoltaic layer adjacent the cathode contact structure, a p-type photovoltaic layer disposed between the anode contact structure and the n-type photovoltaic layer, and an electron blocking layer also disposed between the anode contact structure and the n-type photovoltaic layer. The electron blocking layer provides an energy barrier to electrons that is more than an energy barrier provided to holes.

In some implementations, a boundary between the anode contact structure and the inorganic solar cell defines a first interface surface, and the electron blocking layer prevents electrons in the n-type photovoltaic layer from reaching the first interface surface and permits holes to cross when the inorganic solar cell is generating current.

In some implementations, the electron blocking layer has a band gap that is about 0.2 eV to about 1.0 eV greater than a band gap of the n-type photovoltaic layer.

Another innovative aspect of the subject matter disclosed in this disclosure can be implemented in a method of forming a thin film solar cell device, the method including providing a cathode contact structure, providing an inorganic solar cell adjacent the cathode contact structure, and providing an anode contact structure adjacent the inorganic solar cell on a side of the inorganic solar cell opposite the cathode contact structure. Providing the inorganic solar cell includes providing an n-type photovoltaic layer adjacent the cathode contact structure, providing a p-type photovoltaic layer between the anode contact structure and the n-type photovoltaic layer, and providing an electron blocking layer between the anode contact structure and the n-type photovoltaic layer. The electron blocking layer provides an energy barrier to electrons that is more than an energy barrier provided to holes.

In some implementations, forming the electron blocking layer includes forming the electron blocking layer between the p-type and n-type photovoltaic layers.

Another innovative aspect of the subject matter disclosed in this disclosure can be implemented in a photovoltaic device including an anode contact structure, a cathode contact structure, and an inorganic solar cell disposed between the anode and cathode contact structures. The inorganic solar cell includes an n-type photovoltaic layer adjacent the cathode contact structure, a p-type photovoltaic layer disposed between the anode contact structure and the n-type photovoltaic layer, and a means for blocking electrons disposed between the anode contact structure and the n-type photovoltaic layer. The electron blocking means provides an energy barrier to electrons that is more than an energy barrier provided to holes.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a photovoltaic device providing power to a load.

FIGS. 2A-2E show examples of various implementations of photovoltaic devices that include a minority carrier blocking layer.

FIG. 3 shows an example of a band diagram for a photovoltaic device including a minority carrier blocking layer.

FIGS. 4A-4D show examples of cross-sections of varying implementations of amorphous silicon (a-Si) photovoltaic devices that include a minority carrier blocking layer.

FIGS. 5A-5C show examples of cross-sections of varying implementations of cadmium telluride (CdTe) photovoltaic devices that include a minority carrier blocking layer.

FIGS. 6A-6C show examples of cross-sections of varying implementations of copper indium gallium diselenide (CIGS) photovoltaic devices that include a minority carrier blocking layer.

FIGS. 7A-7H show examples of flow diagrams illustrating various manufacturing processes for photovoltaic devices including a minority carrier blocking layer.

FIGS. 8A-8B show examples of flow diagrams illustrating various manufacturing processes for photovoltaic devices including a minority carrier blocking layer.

### DETAILED DESCRIPTION

Photovoltaic devices including an anode contact structure, a cathode contact structure, and an inorganic solar cell disposed between the anode and cathode contact structures are disclosed. The inorganic solar cell includes a p-type photovoltaic layer, an n-type photovoltaic layer, and one or more minority carrier blocking layers for improving the efficiency of the solar cell by preventing minority carriers within the solar cell from reaching areas where recombination is possible, such as interface recombination surfaces associated with the anode and cathode contact structures. For example, the inorganic solar cell can include a hole blocking layer configured to block holes in the p-type photovoltaic layer from reaching an interface surface between the cathode contact structure and the inorganic solar cell. Similarly, the inorganic solar cell can include an electron blocking layer configured to block electrons in the n-type photovoltaic layer from reaching an interface surface between the anode contact structure and the inorganic solar cell. By including at least one minority carrier blocking layer to prevent minority carriers from reaching interface surfaces, minority carrier recombination can be reduced and solar cell efficiency can be improved.

Implementations of the subject matter described in this disclosure can increase power efficiency of a photovoltaic device, thereby increasing the magnitude of a photocurrent generated from a given amount of light. Additionally, some implementations can be used to reduce recombination losses in thin-film photovoltaic devices such as a-Si, CdTe, and/or CIGS solar cells.

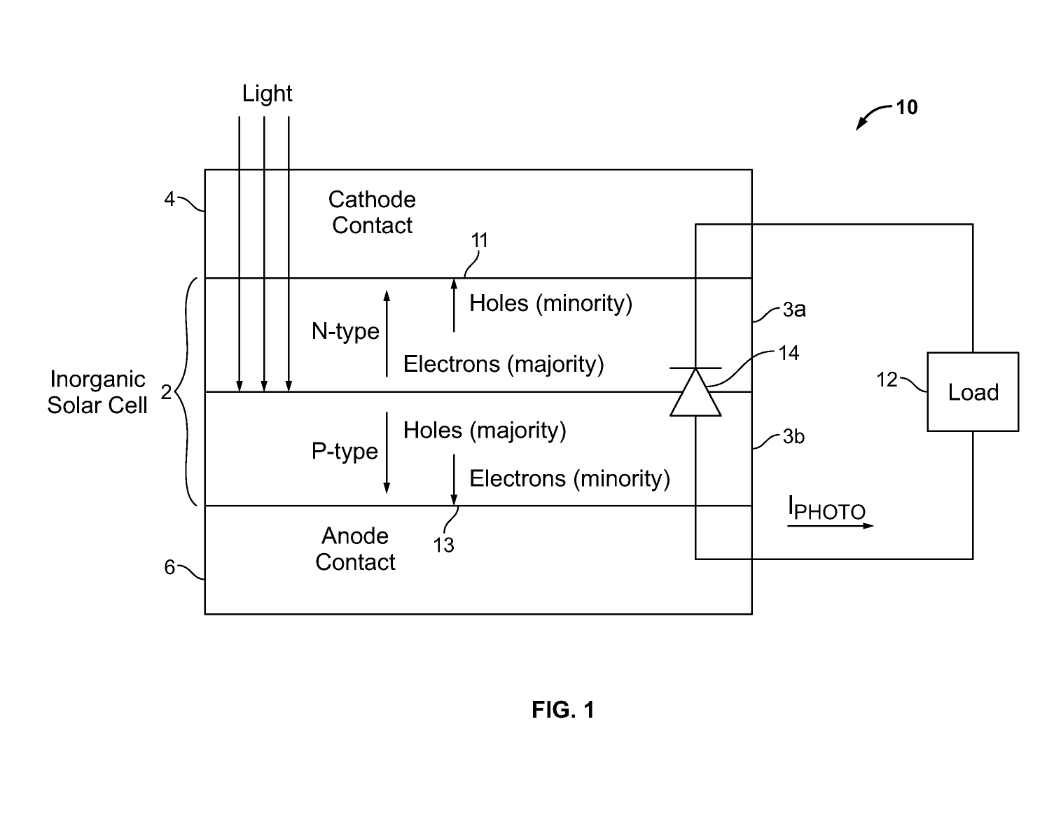

FIG. 1 shows an example of a photovoltaic device 10 providing power to a load 12. The photovoltaic device 10 includes an inorganic solar cell 2, a cathode contact structure 4, and an anode contact structure 6. The inorganic solar cell 2 includes an n-type photovoltaic layer 3a and a p-type photovoltaic layer 3b. The n-type photovoltaic layer 3a is disposed between the cathode contact structure 4 and the p-type photovoltaic layer 3b, and the p-type photovoltaic layer 3b is disposed between the n-type photovoltaic layer 3a and the anode contact structure 6.

The cathode and/or anode contact structures 4 and 6 can be any suitable conductor. For example, the cathode and/or anode contact structures 4 and 6 can include a transparent conductor, including, for example, a transparent conducting oxide (TCO) of zinc oxide (ZnO) or indium tin oxide (ITO). A TCO or other transparent conductor in the photovoltaic device 10 can provide electrical connectivity to the inorganic solar cell 2, while permitting light to pass through the cathode and/or anode contact structures 4 and 6 and reach the inorganic solar cell 2. However, the cathode and/or anode contact structures 4 and 6 need not be transparent. For example, in configurations in which light is configured to pass through only one side of the photovoltaic device 10, the contact structure receiving the light can be transparent, while the other contact structure can be formed from an opaque material, such as a reflector configured to reflect light back toward the inorganic solar cell 2. In some implementations, the anode and/or cathode contact structures 4 and 6 can be formed of an opaque material and can include one or more openings that provide a path for light to reach the inorganic solar cell 2.

The inorganic solar cell 2 can include one or more light absorbing inorganic photovoltaic materials, including, for example, silicon (Si), germanium (Ge), crystalline silicon (c-Si), a-Si, CdTe, copper indium diselenide (CIS), copper indium gallium diselenide (CIGS), and/or III-V semiconductors. The inorganic solar cell 2 can operate as a photodiode 14, which can convert light energy into electrical energy or current. When the inorganic solar cell 2 is illuminated with light, photons from the light transfer energy to the inorganic solar cell 2, which can result in the creation of electron-hole pairs. For example, photons having energy greater than the band-gap of the material(s) in the inorganic solar cell 2 can generate electron-hole pairs within the inorganic solar cell 2 by band-to-band excitation. In addition, high-energy photons can generate electron-hole pairs by impact ionization or via recombination-generation centers within the lattice of the inorganic solar cell 2.

When photons create electron-hole pairs within or near a depletion region of the inorganic solar cell 2, the electric field of the depletion region can sweep the electrons and holes to the anode and cathode contact structures of the photovoltaic device 10, thereby generating a photocurrent. The electron-hole pairs can also move via diffusion through photovoltaic device 10. The generated photocurrent can be used to provide power to any suitable load 12. For example, the load 12 can be power supplied to an electrical grid, or electrical requirements of a mobile device.

The efficiency of the photovoltaic device 10 can be limited by minority carrier recombination occurring at the interfaces between the solar cell 2 and cathode and/or anode contact structures 4 and 6. For example, a cathode interface surface 11 at the boundary between the n-type photovoltaic layer 3a and the cathode contact structure 4 can include interface energy states resulting from dangling bonds, lattice defects, and/or other surface related defects that can operate as recombination centers for minority holes in the n-type photovoltaic layer 3a. Similarly, an anode interface surface 13 at the boundary between the p-type photovoltaic layer 3b and the anode contact structure 6 can include interface energy states that operate as recombination centers for minority electrons in the p-type photovoltaic layer 3b.

The current resulting from the flow of electrons to the interface between the anode contact structure 6 and the p-type layer 3b and the current resulting from the flow of holes to the interface between the cathode contact structure 4 and the n-type layer 3a are in a direction opposite the flow of the photocurrent I_{PHOTO} delivered to the load. Thus, minority carrier recombination at these interfaces reduces the magnitude of the photocurrent generated by the solar cell. Although surface passivation techniques can be employed to reduce the number of interface energy states, there remains a need for reducing minority carrier recombination.

Inorganic solar cells with at least one minority carrier blocking layer are provided. The minority carrier blocking layer can be used to reduce minority carrier recombination, thereby improving efficiency of the inorganic solar cell. For example, a hole blocking layer can be used to block holes from reaching an interface between the solar cell and the cathode contact and/or an electron blocking layer can be used to block electrons from reaching an interface between the solar cell and the anode contact. Since lattice defects and/or surface energy states associated with the interfaces to the anode and cathode contacts can cause minority carrier recombination, blocking the flow of minority carriers to these interfaces can improve efficiency of the inorganic solar cell.

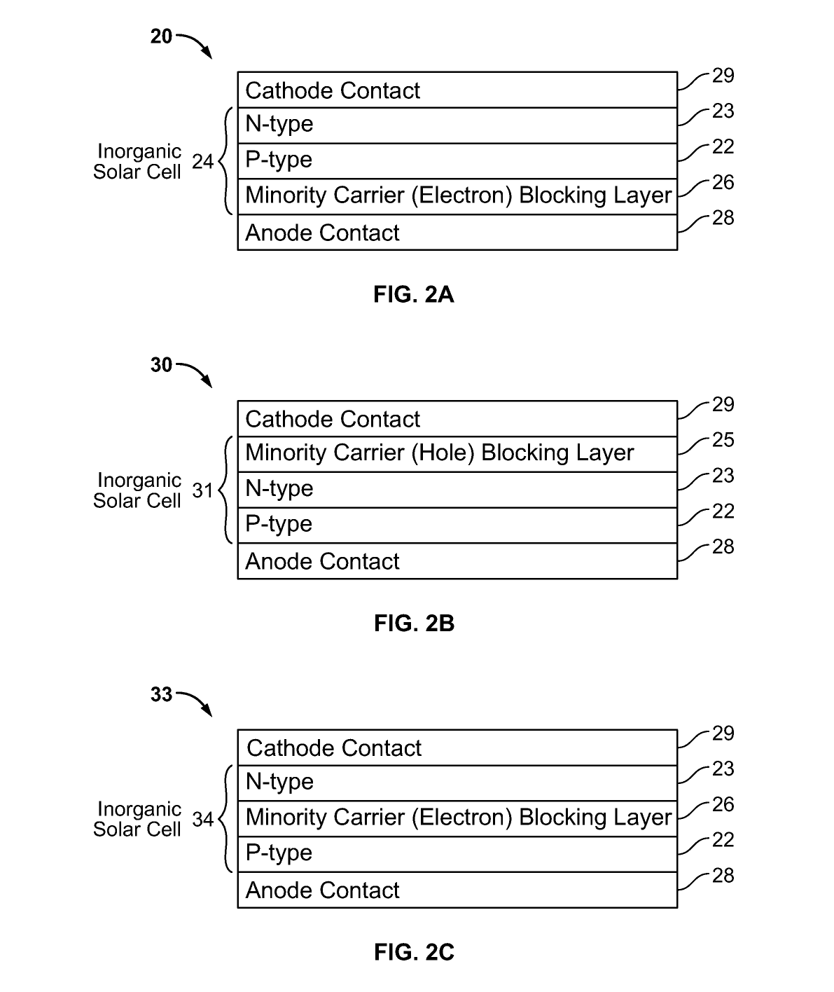

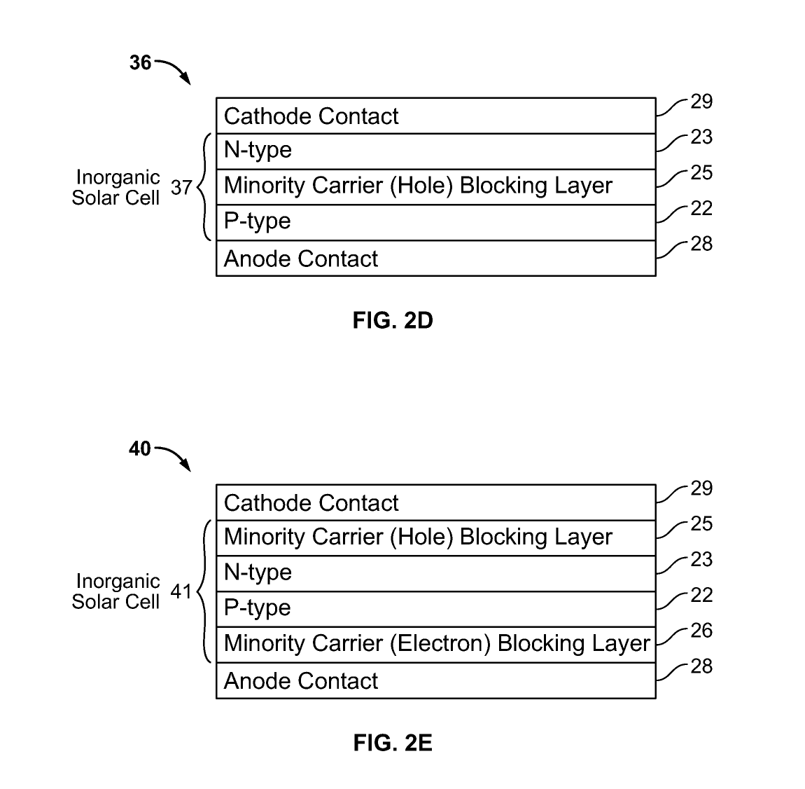

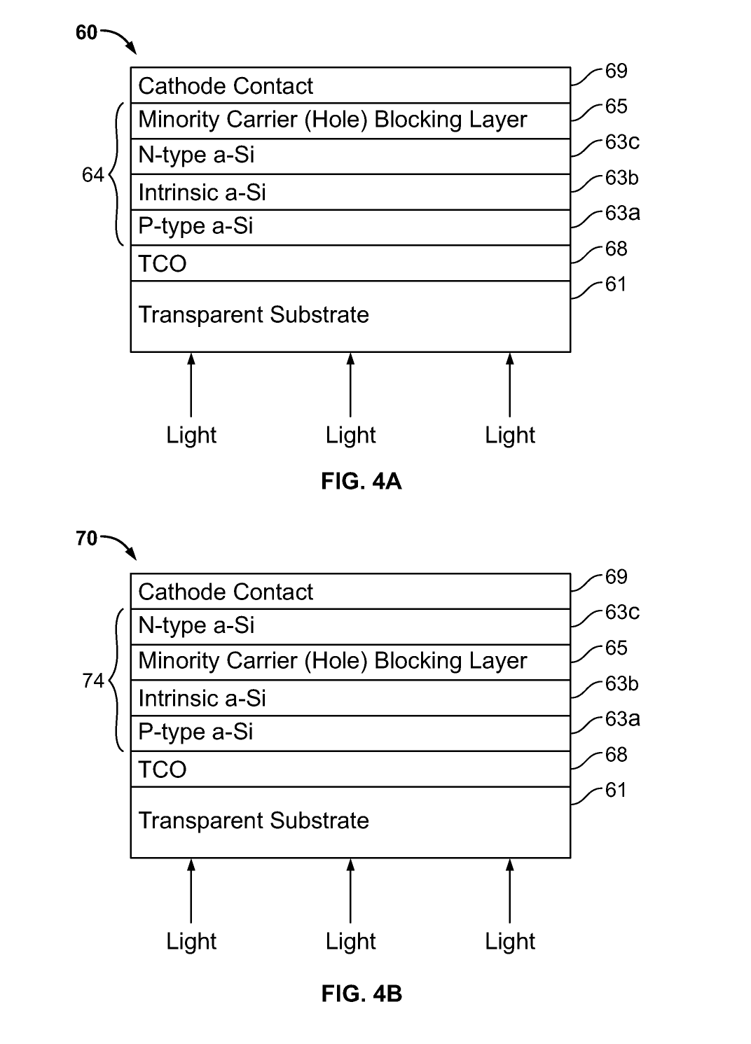

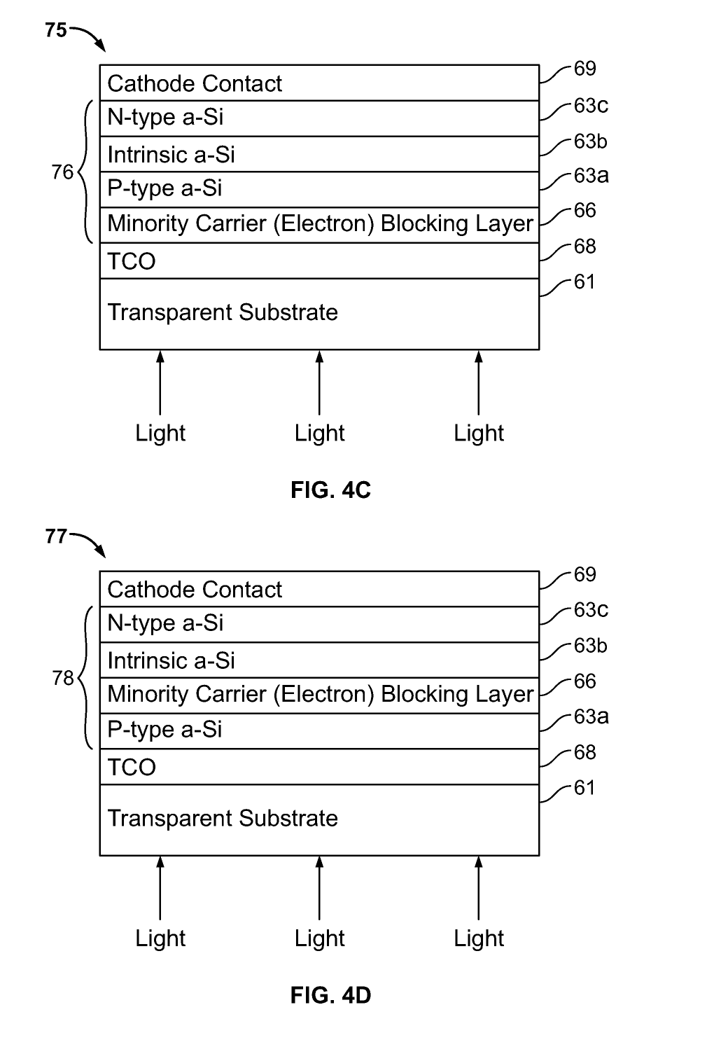

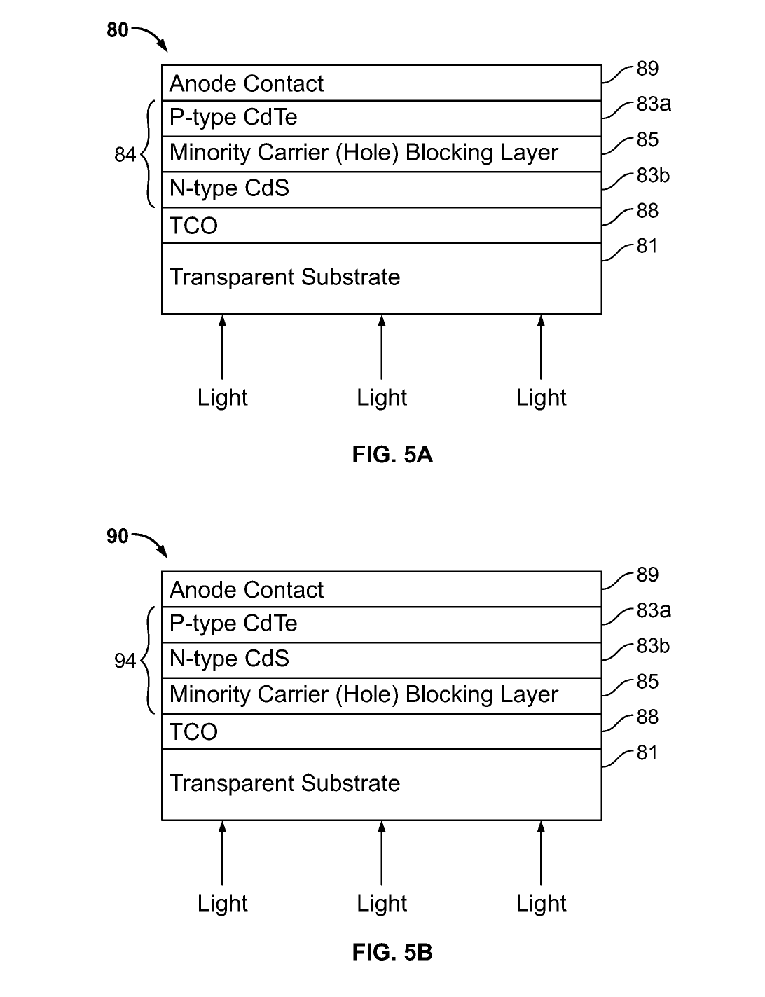

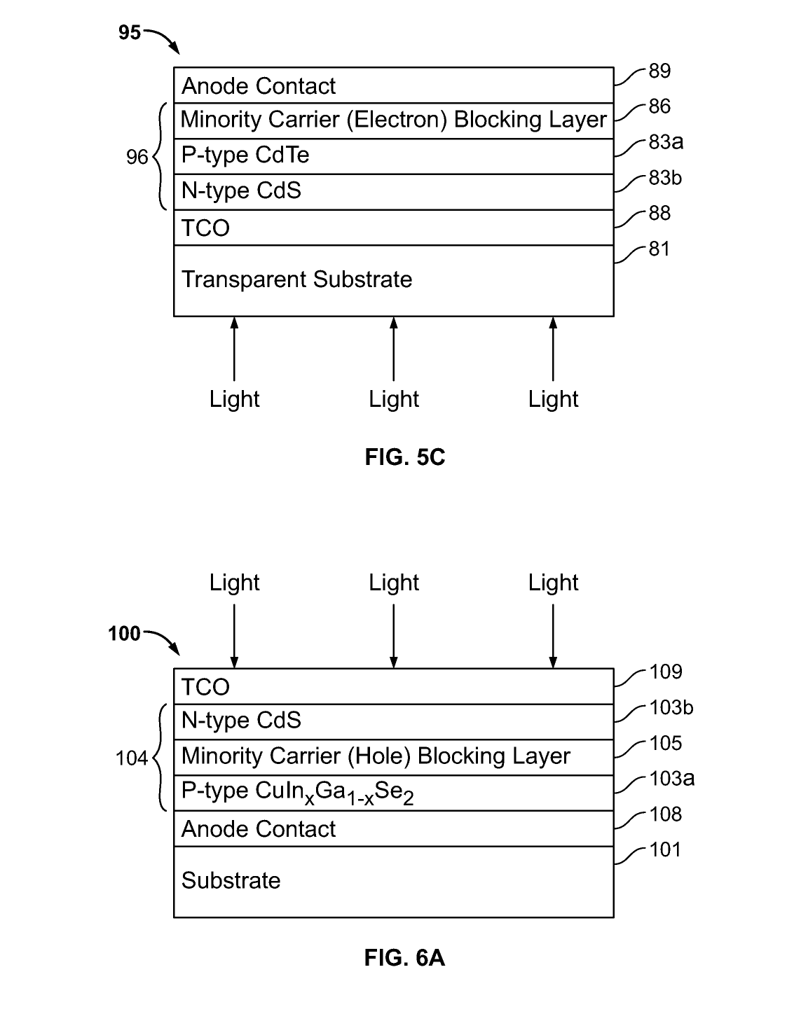

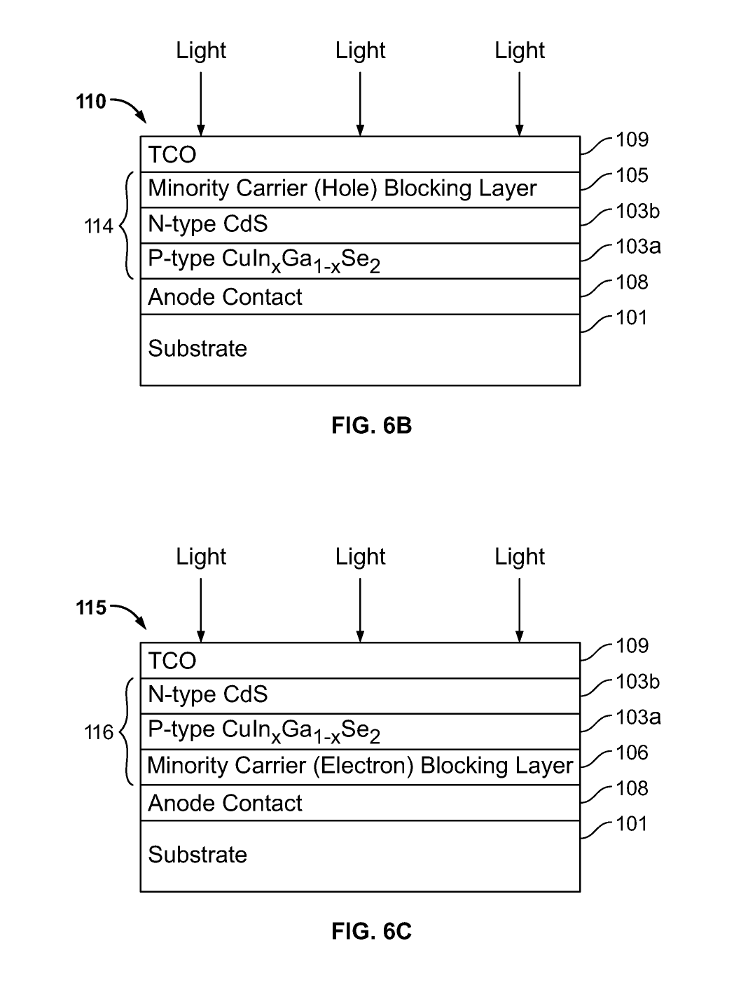

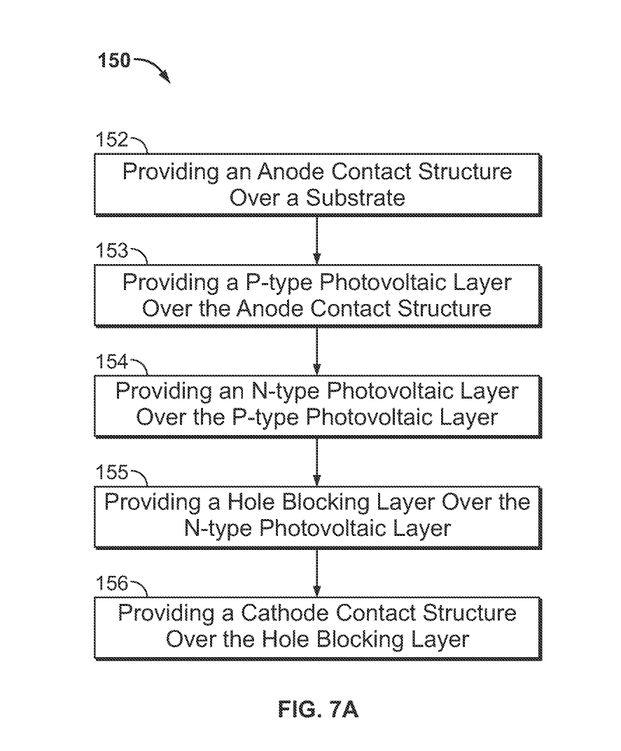

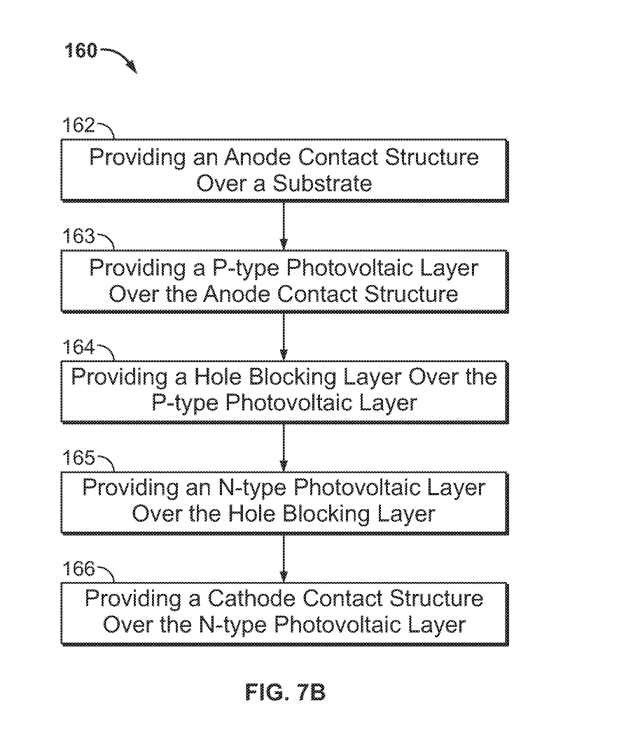

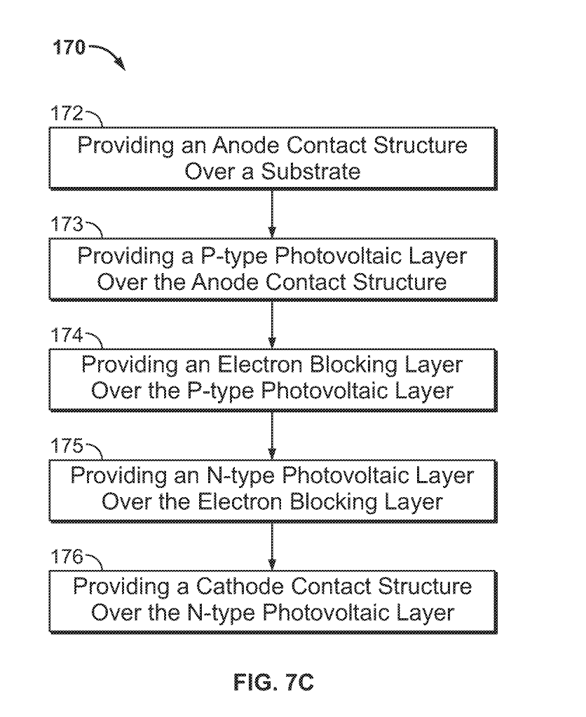

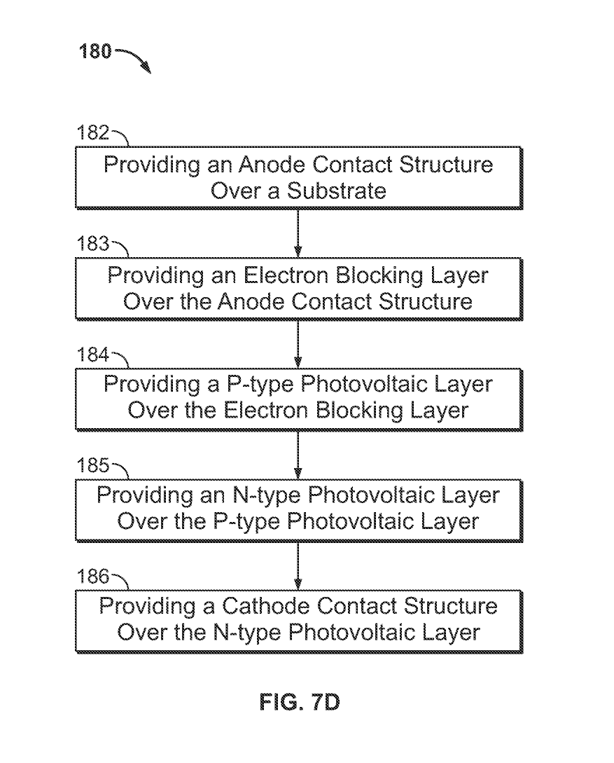

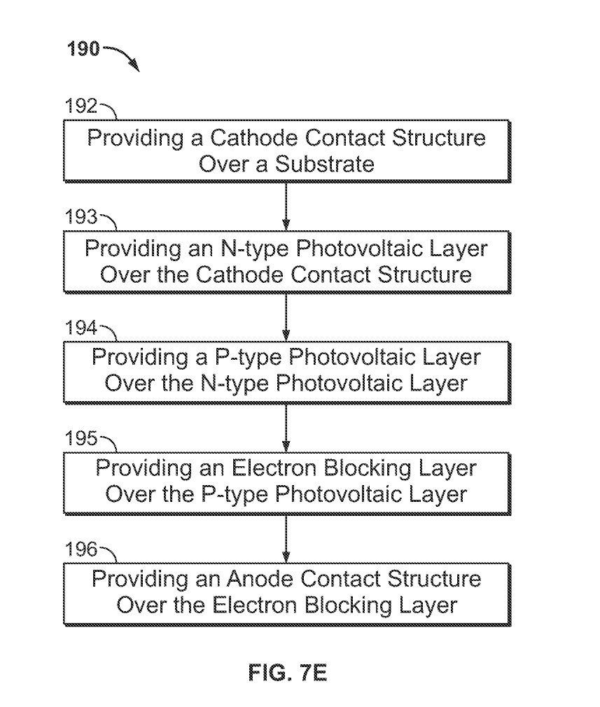

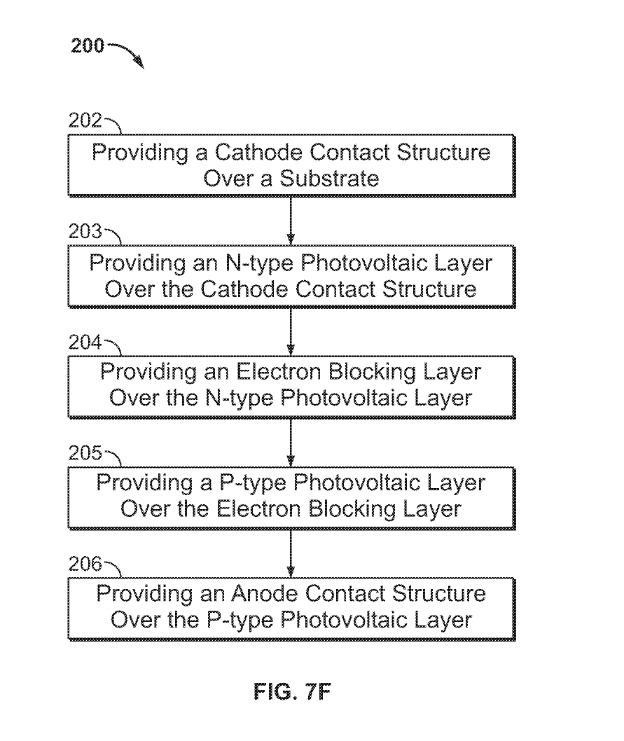

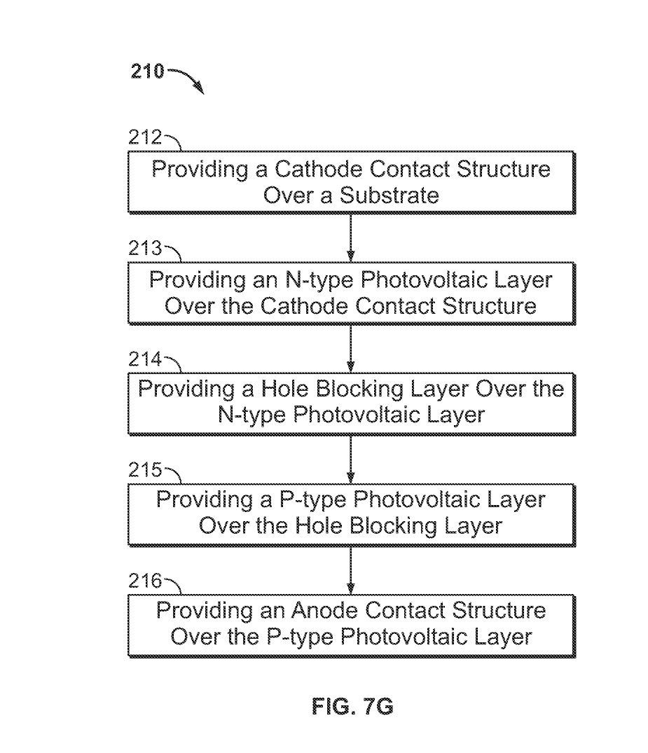

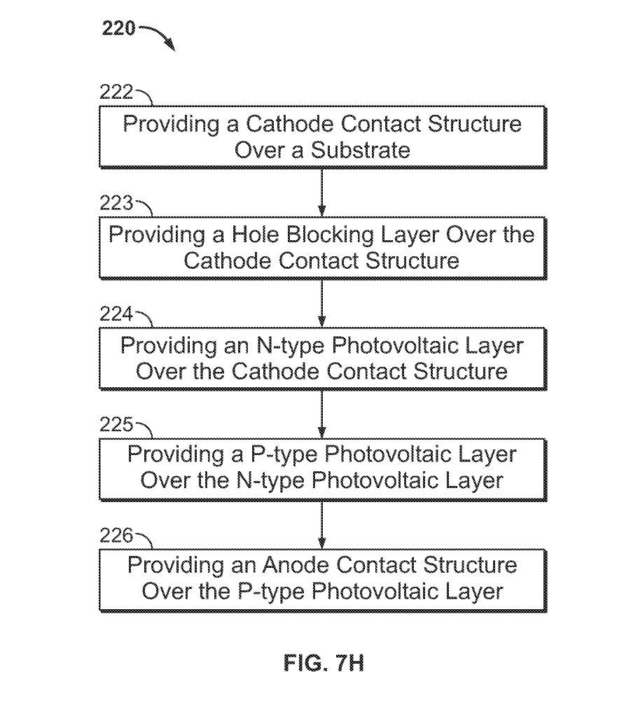

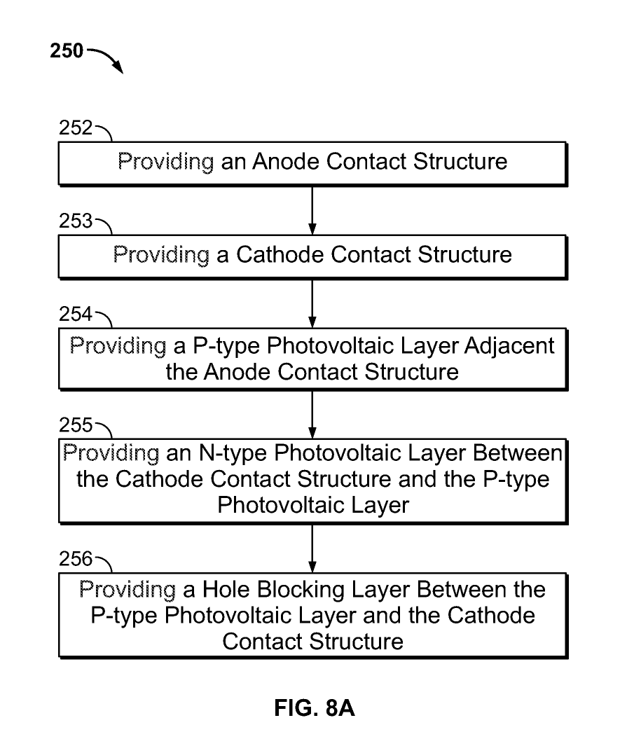

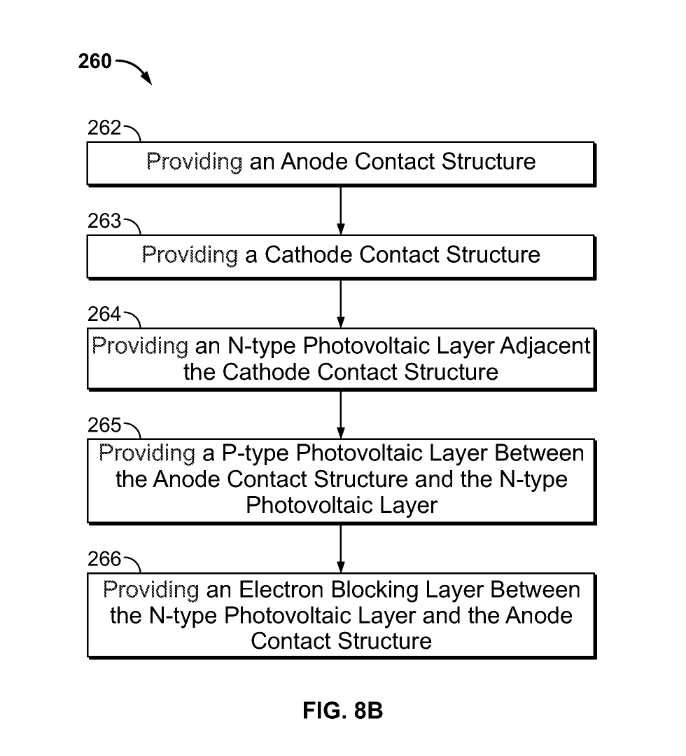

In some implementations, the minority carrier blocking layer can be an electron blocking layer configured to prevent electrons from reaching an interface between the solar cell and the anode contact, as shown, for example, in the configurations illustrated in FIGS. 2A and 2C. The electron blocking layer can be employed in a variety of solar cells, such as p-i-n solar cells (see, for example, FIGS. 4C and 4D), CdTe solar cells (see, for example, FIG. 5C), and CIGS solar cells (see, for example, FIG. 6C). The electron blocking layer can be formed using various methods, such as those shown, for example, in FIGS. 7A, 7B, 7G, 7H, and 8B. In some implementations, the minority carrier blocking layer can be a hole blocking layer configured to prevent holes from reaching an interface between the solar cell and the cathode contact, as shown, for example, in the configurations illustrated in FIGS. 2B and 2D. The hole blocking layer can be employed in a variety of solar cells, such as p-i-n solar cells (see, for example, FIGS. 4A and 4B), CdTe solar cells (see, for example, FIGS. 5A and 5B), and CIGS solar cells (see, for example, FIGS. 6A and 6B). The hole blocking layer can be formed using various methods, such as those shown, for example, in FIGS. 7C-7F and 8A. In some implementations, such as the configuration illustrated in FIG. 2E, a photovoltaic device is provided that includes both a minority carrier blocking layer for preventing electrons from reaching an interface between the solar cell and the anode contact and a minority carrier blocking layer for preventing holes from reaching an interface between the solar cell and the cathode contact.

FIGS. 2A-2E show examples of various implementations of photovoltaic devices that include a minority carrier blocking layer. FIG. 2A shows an example of one implementation of a photovoltaic device 20. The photovoltaic device 20 includes an anode contact structure 28, a cathode contact structure 29, and an inorganic solar cell 24 disposed between the anode and cathode contact structures 28 and 29. The inorganic solar cell 24 includes a p-type photovoltaic layer 22, an n-type photovoltaic layer 23, and an electron blocking layer 26. The n-type photovoltaic layer 23 is disposed between the cathode contact structure 29 and the p-type photovoltaic layer 22, and the electron blocking layer 26 is disposed between the p-type photovoltaic layer 22 and the anode contact structure 28.

The electron blocking layer 26 can operate as a barrier for electrons in the p-type photovoltaic layer 22 from reaching the interface between the inorganic solar cell 24 and the anode contact structure 28. By providing a barrier for electrons from reaching this interface, recombination of electrons at the interface can be decreased, thereby reducing carrier recombination and increasing the probability that the electrons will reach the cathode contact structure 29 and contribute to the generated photocurrent. To avoid hindering the operation of the photovoltaic device 20, the electron blocking layer 26 can be configured to have an energy band level that permits holes to pass across the electron blocking layer 26. Thus, the electron blocking layer 26 can reduce minority carrier recombination without hindering the flow of majority carriers.

FIG. 2B shows an example of another implementation of a photovoltaic device 30. The photovoltaic device 30 includes the anode contact structure 28, the cathode contact structure 29, and an inorganic solar cell 31 disposed between the anode and cathode contact structures 28 and 29. The inorganic solar cell 31 includes the p-type photovoltaic layer 22, the n-type photovoltaic layer 23, and a hole blocking layer 25. The p-type photovoltaic layer 22 is disposed between the anode contact structure 28 and the n-type photovoltaic layer 23, and the hole blocking layer 25 is disposed between the n-type photovoltaic layer 23 and the cathode contact structure 29.

The hole blocking layer 25 can operate as a barrier for holes in the p-type photovoltaic layer 22 from reaching the interface between the inorganic solar cell 31 and the cathode contact structure 29. By providing a barrier for holes in this manner, recombination of holes at the interface can be decreased, thereby reducing carrier recombination and increasing the probability that the holes will reach the anode contact structure and contribute to the generated photocurrent. To avoid hindering the operation of the photovoltaic device 30, the hole blocking layer 25 can be configured to have an energy band level that permits electrons to pass across the hole blocking layer 25.

Minority carrier blocking layers described herein, including but not limited to the electron blocking layer 26 of FIG. 2A and/or the hole blocking layer 25 of FIG. 2B can include materials having a relatively high optical transparency, thereby avoiding interference with the absorption of light by the solar cell. Additionally, the minority carrier blocking layers can be fabricated with a relatively low defect density so as to avoid introducing an additional interface where minority carriers can recombine. In some implementations, the minority carrier blocking layers are formed to include a high majority carrier concentration to aid in providing a low energy barrier to the flow of majority carriers through the minority carrier blocking layer.

FIG. 2C shows an example of another implementation of a photovoltaic device 33. The photovoltaic device 33 includes an anode contact structure 28, a cathode contact structure 29, and an inorganic solar cell 34 disposed between the anode and cathode contact structures 28 and 29. The inorganic solar cell 34 includes a p-type photovoltaic layer 22, a n-type photovoltaic layer 23, and an electron blocking layer 26. The p-type photovoltaic layer 22 is disposed between the electron blocking layer 26 and the anode contact structure 28, and a n-type photovoltaic layer 23 is disposed between the cathode contact structure 29 and the electron blocking layer 26.

The inorganic solar cell 34 of FIG. 2C and the inorganic solar cell 24 of FIG. 2A each include the electron blocking layer 26. However, while the electron blocking layer 26 of FIG. 2A is disposed between the p-type photovoltaic layer 22 and the anode contact structure 28, the electron blocking layer 26 of FIG. 2C is disposed between the n-type photovoltaic layer 23 and the p-type photovoltaic layer 22. In some implementations, such as in the photovoltaic device configuration illustrated in FIG. 2C, the electron blocking layer 26 need not be disposed directly adjacent to the anode contact structure 28. Rather, the electron blocking layer 26 can be disposed in any position suitable for preventing electrons in the n-type photovoltaic layer 23 from crossing into the p-type photovoltaic layer 22 and becoming minority carriers, and thereafter reaching the interface between the inorganic solar cell and the anode contact structure.

FIG. 2D shows an example of another implementation of a photovoltaic device 36. The photovoltaic device 36 includes the anode contact structure 28, the cathode contact structure 29, and an inorganic solar cell 37 disposed between the anode and cathode contact structures 28 and 29. The inorganic solar cell 37 includes the p-type photovoltaic layer 22, the n-type photovoltaic layer 23, and the hole blocking layer 25. The p-type photovoltaic layer 22 is disposed between the hole blocking layer 25 and the anode contact structure 28, and the n-type photovoltaic layer 23 is disposed between the cathode contact structure 29 and the hole blocking layer 25.

The inorganic solar cell 37 of FIG. 2D illustrates a configuration in which the hole blocking layer 25 is not disposed directly adjacent to the cathode contact structure 29. In some implementations, the hole blocking layer 25 can be disposed in any suitable position that prevents holes in the p-type photovoltaic layer 22 from crossing into the n-type photovoltaic layer 23 and becoming minority carriers, and thereafter reaching the interface between the inorganic solar cell and the cathode contact structure 29.

FIG. 2E shows an example of another implementation of a photovoltaic device 40. The photovoltaic device 40 includes the anode contact structure 28, the cathode contact structure 29, and an inorganic solar cell 41 disposed between the anode and cathode contact structures 28 and 29. The inorganic solar cell 41 includes the p-type photovoltaic layer 22, the n-type photovoltaic layer 23, the hole blocking layer 25 and the electron blocking layer 26. The hole blocking layer 25 is disposed between the cathode contact structure 29 and the n-type photovoltaic layer 23, the electron blocking layer 26 is disposed between the p-type photovoltaic layer 22 and the anode contact structure 28, and the p-type photovoltaic layer 22 is disposed adjacent the n-type photovoltaic layer 23.

FIG. 2E illustrates a configuration in which the photovoltaic device 40 includes both the hole blocking layer 25 and the electron blocking layer 26. By including a plurality of minority carrier blocking layers, the efficiency of a photovoltaic device can be improved. Although FIG. 2E illustrates one example implementation including both a hole blocking layer 25 and an electron blocking layer 26, other configurations are possible. For example, in one implementation the hole blocking layer 25 can be disposed between the cathode contact structure 29 and the n-type photovoltaic layer 23. In another implementation, the electron blocking layer 26 can be disposed between n-type photovoltaic layer 23 and the p-type photovoltaic layer 22. Additionally, in another implementation the hole blocking layer 25 can be disposed between the n-type photovoltaic layer 23 and the electron blocking layer 26, and the electron blocking layer 26 can be disposed between the hole blocking layer 25 and the p-type photovoltaic layer 22. Furthermore, in another implementation the hole blocking layer 25 can be disposed between the n-type photovoltaic layer 23 and the p-type photovoltaic layer 22, and the electron blocking layer 26 can be disposed between the p-type photovoltaic layer 22 and the anode contact structure 28.

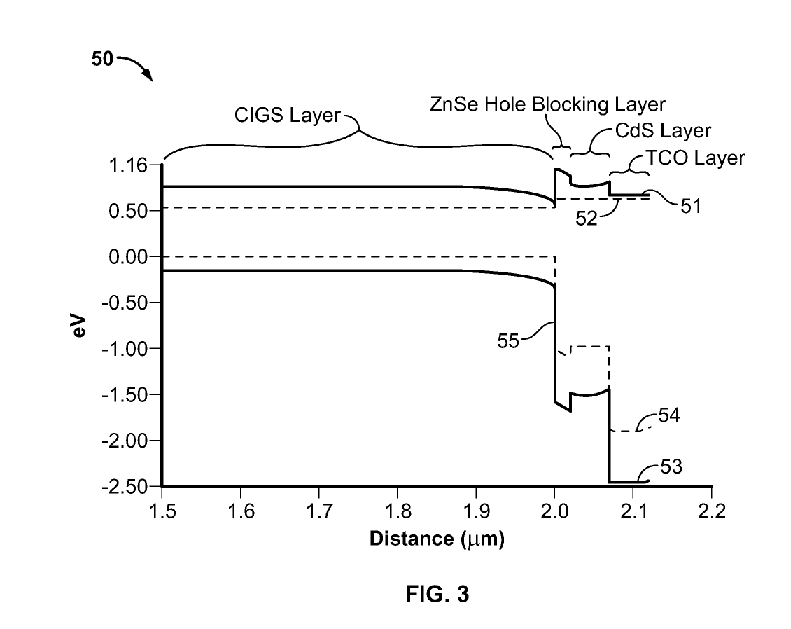

FIG. 3 shows an example of a band diagram 50 for a photovoltaic device including a minority carrier blocking layer. The illustrated band diagram 50 illustrates energy (eV) as a function of distance (or position) for a conduction band 51, an electron quasi-Fermi level 52, a valence band 53, and a hole quasi-Fermi level 54. The illustrated band diagram 50 is for a photovoltaic device including a cadmium selenium (CdS) p-type photovoltaic layer, a zinc selenide (ZnSe) hole blocking layer adjacent the p-type photovoltaic layer, a CIGS n-type photovoltaic layer adjacent the hole blocking layer, and a TCO cathode contact structure adjacent the n-type photovoltaic layer. The illustrated band diagram 50 does not illustrate the energy levels in the anode contact structure. However, the photovoltaic device can include an anode contact structure adjacent the p-type photovoltaic layer on a side of the p-type photovoltaic layer opposite the hole blocking layer. The band diagram 50 can correspond to one implementation of a photovoltaic device arranged in the configuration shown in FIG. 2D.

The hole blocking layer has generated an energy barrier 55 for holes in the p-type photovoltaic layer from reaching the n-type photovoltaic layer. In certain implementations, a hole blocking layer can be configured to provide an energy barrier 55 to holes that is have about 0.2 eV to about 1.0 eV greater than the energy barrier provided to electrons, for example about 0.2 eV to about 0.5 eV. Likewise, in certain implementations, an electron blocking layer can be configured to provide an energy barrier to electrons that is about 0.2 eV to about 1.0 eV greater than the energy barrier provided to holes.

As illustrated in FIG. 3, the hole blocking layer can have a band gap greater than that of the n-type photovoltaic layer, and the energy bands for the minority carrier blocking layer can be offset with respect to the doped layer to aid in providing an energy barrier to suppress minority carrier diffusion. In certain implementations, a hole blocking layer has a band gap that is about 0.2 eV to about 1.0 eV greater than a band gap of the p-type photovoltaic layer, for example about 0.2 eV to about 0.5 eV. Similarly, in certain implementations, an electron blocking layer has a band gap that is about 0.2 eV to about 1.0 eV greater than a band gap of the n-type photovoltaic layer.

The minority carrier blocking layer can be relatively thin. Providing a relatively thin minority carrier blocking layer can allow a greater number of majority carriers to cross the minority carrier blocking layer when the inorganic solar cell is generating a photocurrent relative to a scheme in which the minority carrier blocking layer has a relatively large thickness. In some implementations, the minority carrier blocking layer has a thickness ranging between about 1 nm and about 10 nm.

FIGS. 4A-4D show examples of cross-sections of varying implementations of a-Si photovoltaic devices that include a minority carrier blocking layer.

FIG. 4A shows an example of a photovoltaic device 60 including a transparent substrate 61, a TCO structure 68 disposed over the transparent substrate 61, a solar cell 64 disposed over the TCO structure 68, and a cathode contact structure 69 disposed over the solar cell 64. The solar cell 64 includes a p-type a-Si layer 63a adjacent the TCO structure 68, an intrinsic a-Si layer 63b adjacent the p-type a-Si layer 63a, an n-type a-Si layer 63c adjacent the intrinsic a-Si layer 63b, and a hole blocking layer 65 adjacent the n-type a-Si layer 63c.

The transparent substrate 61 can be a glass substrate or any other suitable transparent substrate, such as an optical plastic. The transparent substrate 61 can be employed to structurally support the TCO layer 68, the solar cell 64, and the cathode contact structure 69, each of which can be formed on the transparent substrate 61 using thin film technology. Accordingly, the TCO layer 68, the solar cell 64, and the cathode contact structure 69 can be formed from a plurality of thin film layers deposited on a surface of the transparent substrate 61. The transparent substrate 61 can have any suitable thickness, such as a thickness ranging between about 0.025 mm to about 10 mm.

The solar cell 64 can receive light through the transparent substrate 61 and the TCO structure 68. The solar cell 64 shown in FIG. 4A includes a p-i-n junction structure formed from the p-type a-Si layer 63a, the intrinsic a-Si layer 63b, and the n-type a-Si layer 63c. Since a p-i-n junction structure can have a depletion region that is larger than a depletion region of a p-n junction structure, using a p-i-n junction structure can increase the light absorption and the magnitude of the photocurrent generated by the solar cell 64. For example, electron-hole pairs generated by light photons within or near the depletion region can be swept by the electric field of the depletion region to create the photocurrent, and thus a depletion region of a larger size can lead to an increase in the magnitude of the photocurrent. In one implementation, the solar cell 64 has a thickness ranging between about 50 nm and about 500 nm.

The solar cell 64 also includes the hole blocking layer 65, which has been disposed along the path between the n-type a-Si layer 63c and the cathode contact structure 69 so as to prevent holes from reaching an interface between the solar cell 64 and the cathode contact structure 69. In certain implementations, the hole blocking layer 65 can be an n-type a-Si layer having a band gap that is about 0.05 eV to about 0.3 eV greater than a band gap of the n-type a-Si layer 63c. The hole blocking layer 65 can have any suitable thickness, such as a thickness in the range of about 1 nm to about 10 nm.

The TCO structure 68 can operate as an anode contact structure for the solar cell 64. The solar cell 64 also includes the cathode contact structure 69, which can include any material suitable for making electrical contact with the solar cell cathode. In certain implementations, the cathode contact structure 69 can include a reflective metal, such as aluminum (Al) and/or silver (Ag). Including a reflective metal in the cathode contact structure 69 can help reflect light that passes through the inorganic solar cell 64 back toward the solar cell, thereby increasing the energy efficiency of the photovoltaic device 60.

FIG. 4B shows an example of a photovoltaic device 70 including the transparent substrate 61, the TCO structure 68 disposed over the transparent substrate 61, a solar cell 74 disposed over the TCO structure 68, and a cathode contact structure 69 disposed over the solar cell 74. The solar cell 74 includes the p-type a-Si layer 63a adjacent the TCO structure 68, the intrinsic a-Si layer 63b adjacent the p-type a-Si layer 63a, the hole blocking layer 65 adjacent the intrinsic a-Si layer 63b, and the n-type a-Si layer 63c adjacent the hole blocking layer 65.

The photovoltaic device 70 of FIG. 4B is similar to the photovoltaic device 60 of FIG. 4A. However, in the configuration illustrated in FIG. 4B, the order of the hole blocking layer 65 and the n-type a-Si layer 63c has been reversed relative to the order shown in FIG. 4A. In some implementations, the hole blocking layer 65 can be provided in any position suitable for preventing holes from reaching a recombination surface disposed along the boundary between the solar cell and the cathode contact structure.

FIG. 4C shows an example of a photovoltaic device 75 including a transparent substrate 61, a TCO structure 68 disposed over the transparent substrate 61, a solar cell 76 disposed over the TCO structure 68, and a cathode contact structure 69 disposed over the solar cell 76. The solar cell 76 includes an electron blocking layer 66 adjacent the TCO structure 68, a p-type a-Si layer 63a adjacent the electron blocking layer 66, an intrinsic a-Si layer 63b adjacent the p-type a-Si layer 63a, and an n-type a-Si layer 63c adjacent the intrinsic a-Si layer 63b.

The electron blocking layer 66 has been disposed along the path between the p-type a-Si layer 63a and the TCO structure 68 so as to prevent electrons from reaching an interface between the solar cell 76 and the TCO structure 68. In certain implementations, the electron blocking layer 66 can be a p-type a-Si layer having a band gap that is about 0.05 eV to about 0.5 eV greater than a band gap of the p-type a-Si layer 63a. In some implementations, the electron blocking layer 66 can have, for example, a thickness in the range of about 1 nm to about 10 nm.

Certain features of the photovoltaic device 75 of FIG. 4C can be similar to those described above with respect to the photovoltaic device 60 of FIG. 4A.

FIG. 4D shows an example of a photovoltaic device 77 including the transparent substrate 61, the TCO structure 68 disposed over the transparent substrate 61, a solar cell 78 disposed over the TCO structure 68, and a cathode contact structure 69 disposed over the solar cell 78. The solar cell 78 includes the p-type a-Si layer 63a adjacent the TCO structure 68, the electron blocking layer 66 adjacent the p-type a-Si layer 63a, the intrinsic a-Si layer 63b adjacent the electron blocking layer 66, and the n-type a-Si layer 63c adjacent the intrinsic a-Si layer 63b.

Features of photovoltaic device 77 of FIG. 4D can be similar to the photovoltaic device 75 of FIG. 4C. However, in the configuration illustrated in FIG. 4D, the order of the electron blocking layer 66 and the p-type amorphous silicon (a-Si) layer 63a has been reversed relative to the order shown in FIG. 4C.

FIGS. 5A-5C show examples of cross-sections of varying implementations of CdTe photovoltaic devices that include a minority carrier blocking layer.

FIG. 5A shows an example of a photovoltaic device 80 including a transparent substrate 81, a TCO structure 88 disposed over the transparent substrate 81, a solar cell 84 disposed over the TCO structure 88, and an anode contact structure 89 disposed over the solar cell 84. The solar cell 84 includes an n-type CdS layer 83b adjacent the TCO structure 88, a hole blocking layer 85 adjacent the n-type CdS layer 83b, and a p-type CdTe layer 83a adjacent the hole blocking layer 85.

The transparent substrate 81 can be a glass substrate or any other suitable transparent substrate, such as an optical plastic. The transparent substrate 81 can be employed to structurally support the TCO layer 88, the solar cell 84, and the anode contact structure 89, each of which can be formed on the transparent substrate 81 using thin film technology. Additional details of the transparent substrate 81 can be similar to those described earlier.

The solar cell 84 can receive light through the transparent substrate 81 and the TCO structure 88. The solar cell 84 shown in FIG. 5A includes a heterojunction structure including the p-type CdTe layer 83a and the n-type CdS layer 83b. In some implementations, the solar cell 84 has a thickness in the range of about 1 μm to about 10 μm. The solar cell 84 also includes the hole blocking layer 85, which has been disposed along the path between the p-type CdTe layer 83a and the TCO structure 88 so as to prevent holes from reaching an interface between the solar cell 84 and the TCO structure 88. In certain implementations, the hole blocking layer 85 includes at least one of ZnSe, an alloy of cadmium oxide and zinc oxide in a ratio of x and 1-x (CdₓZn₁₋ₓS), an alloy of cadmium sulfide and zinc sulfide in a ratio of x and 1-x (CdₓZn₁₋ₓS), indium sulfide (In₂S₃), and zinc oxysulfide (ZnOₓS₁₋ₓ). The hole blocking layer 85 can have any suitable thickness, such as a thickness in the range of about 1 nm to about 10 nm.

The TCO structure 88 can operate as a cathode contact structure for the solar cell 84. The solar cell 84 also includes the anode contact structure 89, which can include any material suitable for making electrical contact with the solar cell anode. In certain implementations, the anode contact structure 89 can include a reflective metal, such as nickel-aluminum (Ni—Al) and/or gold (Au).

FIG. 5B shows an example of a photovoltaic device 90 including the transparent substrate 81, the TCO structure 88 disposed over the transparent substrate 81, a solar cell 94 disposed over the TCO structure 88, and the anode contact structure 89 disposed over the solar cell 94. The solar cell 94 includes the hole blocking layer 85 adjacent the TCO structure 88, the n-type CdS layer 83b adjacent the hole blocking layer 85, and the p-type CdTe layer 83a adjacent the n-type CdS layer 83b.

Certain features of photovoltaic device 90 of FIG. 5B can be similar to the photovoltaic device 80 of FIG. 5A. However, in the configuration illustrated in FIG. 5B, the order of the hole blocking layer 85 and the n-type CdS layer 83b has been reversed relative to the order shown in FIG. 5A. In some implementations, the hole blocking layer 85 can be provided in any position suitable for preventing holes from reaching a recombination surface disposed along the boundary between the solar cell and the cathode contact structure.

FIG. 5C shows an example of a photovoltaic device 95 including the transparent substrate 81, the TCO structure 88 disposed over the transparent substrate 81, a solar cell 96 disposed over the TCO structure 88, and the anode contact structure 89 disposed over the solar cell 96. The solar cell 96 includes the n-type CdS layer 83b adjacent the TCO structure 88, the p-type CdTe layer 83a adjacent the n-type CdS layer 83b, and an electron blocking layer 86 adjacent the p-type CdTe layer 83a.

The electron blocking layer 86 has been disposed along the path between the p-type CdTe layer 83a and the anode contact structure 89 so as to prevent electrons from reaching an interface between the solar cell 96 and the anode contact structure 89. In certain implementations, the electron blocking layer 86 includes at least one of ZnSe, an alloy of cadmium telluride and zinc telluride in a ratio of x and 1-x (CdₓZn₁₋ₓTe), an alloy of cadmium selenide and zinc selenide in a ratio of x and 1-x (CdₓZn₁₋ₓSe), an alloy of cadmium sulfide and cadmium telluride in a ratio of x and 1-x (CdₓTe₁₋ₓSₓ), an alloy of cadmium selenide and cadmium telluride in a ratio of x and 1-x (CdTe₁₋ₓSeₓ), an alloy of cadmium selenide and cadmium sulfide in a ratio of 1-x and x (CdSe₁₋ₓSₓ), an alloy of mercury sulfide and mercury telluride in a ratio of x and 1-x (HgTe₁₋ₓSₓ), and an alloy of mercury selenide and mercury sulfide in a ratio of 1-x and x (HgSe₁₋ₓSₓ). The electron blocking layer 86 can have any suitable thickness, such as a thickness in the range of about 1 nm to about 10 nm.

Additional details of the photovoltaic device 95 of FIG. 5C can be similar to those described above with respect to the photovoltaic device 80 of FIG. 5A.

Although FIG. 5C illustrates a configuration in which the electron blocking layer 86 has been disposed between the anode contact structure 89 and the p-type CdTe layer 83a, the photovoltaic device 95 can be configured such that the electron blocking layer 86 is disposed between the p-type CdTe layer 83a and the n-type CdS layer 83b.

FIGS. 6A-6C show examples of cross-sections of varying implementations of CIGS photovoltaic devices that include a minority carrier blocking layer.

FIG. 6A shows an example of a photovoltaic device 100 including a substrate 101, an anode contact structure 108 disposed over the substrate 101, a solar cell 104 disposed over the anode contact structure 108, and a TCO structure 109 disposed over the solar cell 104. The solar cell 104 includes a p-type copper indium gallium selenide (CuInₓGa₁₋ₓSe) or CIGS layer 103a adjacent the anode contact structure 108, a hole blocking layer 105 adjacent the p-type CIGS layer 103a, and an n-type CdS layer 103b adjacent the hole blocking layer 105.

The substrate 101 can be a glass substrate or any other suitable substrate, including an opaque substrate. The substrate 101 can be used to structurally support the anode contact structure 108, the solar cell 104, and the TCO structure 109, each of which can be formed on the substrate 101 using thin film technology. The anode contact structure 108 can include any material suitable for making electrical contact with the solar cell anode, including, for example, molybdenum (Mo). The TCO structure 109 can operate as the cathode contact structure of the solar cell 104.

The solar cell 104 can receive light through the TCO structure 109. In some implementations, the solar cell 104 has a thickness in the range of about 1 μm to about 10 μm. The solar cell 104 shown in FIG. 6A includes the hole blocking layer 105, which has been disposed along the path between the p-type CIGS layer 103a and the TCO structure 109 so as to prevent holes from reaching an interface between the solar cell 104 and the TCO structure 109. In certain implementations, the hole blocking layer 105 includes at least one of zinc selenide (ZnSe), CdₓZn₁₋ₓO, CdₓZn₁₋ₓS, indium sulfide (In₂S₃), and zinc oxysulfide (ZnOₓS₁₋ₓ). The hole blocking layer 105 can have any suitable thickness, such as a thickness in the range of about 1 nm to about 10 nm.

FIG. 6B shows an example of a photovoltaic device 110 including the substrate 101, the anode contact structure 108 disposed over the substrate 101, the solar cell 114 disposed over the anode contact structure 108, and the TCO structure 109 disposed over the solar cell 114. The solar cell 114 includes the p-type copper indium gallium selenide (CuInₓGa₁₋ₓSe₂) or CIGS layer 103a adjacent the anode contact structure 108, the n-type CdS layer 103b adjacent the p-type CIGS layer 103a, and the hole blocking layer 105 adjacent the n-type CdS layer 103b.

The photovoltaic device 110 of FIG. 6B is similar to the photovoltaic device 100 of FIG. 6A. However, in the configuration illustrated in FIG. 6B, the order of the hole blocking layer 105 and the n-type CdS layer 103b has been reversed relative to the order shown in FIG. 6A. In some implementations, the hole blocking layer 105 can be provided in any position suitable for preventing holes from reaching a recombination surface disposed along the boundary between the solar cell and the cathode contact structure.

FIG. 6C shows an example of a photovoltaic device 115 including the substrate 101, the anode contact structure 108 disposed over the substrate 101, a solar cell 116 disposed over the anode contact structure 108, and the TCO structure 109 disposed over the solar cell 116. The solar cell 116 includes an electron blocking layer 106 disposed adjacent the anode contact structure 108, the p-type CIGS layer 103a adjacent the electron blocking layer 106, and the n-type CdS layer 103b adjacent the p-type CIGS layer 103a.

The electron blocking layer 106 has been disposed along the path between the p-type CIGS layer 103a and the anode contact structure 108 so as to prevent electrons from reaching an interface between the solar cell 116 and the anode contact structure 108. In certain implementations, the electron blocking layer 106 includes at least one of ZnSe, CdₓZn₁₋ₓTe, CdₓZn₁₋ₓSe, CdTe₁₋ₓSₓ, CdTe₁₋ₓSeₓ, CdSe₁₋ₓSₓ, HgTe₁₋ₓSₓ, and HgSe₁₋ₓSₓ. The electron blocking layer 106 can have any suitable thickness, such as a thickness in the range of about 1 nm to about 10 nm.

Additional details of the photovoltaic device 115 of FIG. 6C can be similar to those described above with respect to the photovoltaic device 100 of FIG. 6A.

Although FIG. 6C illustrates a configuration in which the electron blocking layer 106 has been disposed between the anode contact structure 108 and the p-type CIGS layer 103a, the photovoltaic device 115 can be configured such that the electron blocking layer 106 is disposed between the p-type CIGS layer 103a and the n-type CdS layer 103b.

FIGS. 7A-7H show examples of flow diagrams illustrating various manufacturing processes for photovoltaic devices including a minority carrier blocking layer.

FIG. 7A shows an example of a flow diagram illustrating a manufacturing process 150 for a photovoltaic device including a hole blocking layer. The illustrated process 150 starts at block 152, in which an anode contact structure is provided over a substrate. The process 150 continues at block 153, in which a p-type photovoltaic layer is provided over the anode contact structure. In a block 154, an n-type photovoltaic layer is provided over the p-type photovoltaic layer. The process 150 continues at block 155, in which a hole blocking layer is provided over the n-type photovoltaic layer. In block 156, a cathode contact structure is provided over the hole blocking layer.

FIG. 7B shows an example of a flow diagram illustrating a manufacturing process 160 for a photovoltaic device including a hole blocking layer. The illustrated process 160 starts at block 162, in which an anode contact structure is provided over a substrate. The process 160 continues at block 163, in which a p-type photovoltaic layer is provided over the anode contact structure. In a block 164, a hole blocking layer is provided over the p-type photovoltaic layer. The process 160 continues at block 165, in which an n-type photovoltaic layer is provided over the hole blocking layer. In block 166, a cathode contact structure is provided over the n-type photovoltaic layer.

FIG. 7C shows an example of a flow diagram illustrating a manufacturing process 170 for a photovoltaic device including an electron blocking layer. The illustrated process 170 starts at block 172, in which an anode contact structure is provided over a substrate. The process 170 continues at block 173, in which a p-type photovoltaic layer is provided over the anode contact structure. In a block 174, an electron blocking layer is provided over the p-type photovoltaic layer. The process 170 continues at block 175, in which an n-type photovoltaic layer is provided over the electron blocking layer. In block 176, a cathode contact structure is provided over the n-type photovoltaic layer.

FIG. 7D shows an example of a flow diagram illustrating a manufacturing process 180 for a photovoltaic device including an electron blocking layer. The illustrated process 180 starts at block 182, in which an anode contact structure is provided over a substrate. The process 180 continues at block 183, in which an electron blocking layer is provided over the anode contact structure. In a block 184, a p-type photovoltaic layer is provided over the electron blocking layer. The process 180 continues at block 185, in which an n-type photovoltaic layer is provided over the p-type photovoltaic layer. In block 186, a cathode contact structure is provided over the n-type photovoltaic layer.

FIG. 7E shows an example of a flow diagram illustrating a manufacturing process 190 for a photovoltaic device including an electron blocking layer. The illustrated process 190 starts at block 192, in which a cathode contact structure is provided over a substrate. The process 190 continues at block 193, in which an n-type photovoltaic layer is provided over the cathode contact structure. In a block 194, a p-type photovoltaic layer is provided over the n-type photovoltaic layer. The process 190 continues at block 195, in which an electron blocking layer is provided over the p-type photovoltaic layer. In block 196, an anode contact structure is provided over the electron blocking layer.

FIG. 7F shows an example of a flow diagram illustrating a manufacturing process 200 for a photovoltaic device including an electron blocking layer. The illustrated process 200 starts at block 202, in which a cathode contact structure is provided over a substrate. The process 200 continues at block 203, in which an n-type photovoltaic layer is provided over the cathode contact structure. In a block 204, an electron blocking layer is provided over the n-type photovoltaic layer. The process 200 continues at block 205, in which a p-type photovoltaic layer is provided over the electron blocking layer. In block 206, an anode contact structure is provided over the p-type photovoltaic layer.

FIG. 7G shows an example of a flow diagram illustrating a manufacturing process 210 for a photovoltaic device including a hole blocking layer. The illustrated process 210 starts at block 212, in which a cathode contact structure is provided over a substrate. The process 210 continues at block 213, in which an n-type photovoltaic layer is provided over the cathode contact structure. In a block 214, a hole blocking layer is provided over the n-type photovoltaic layer. The process 210 continues at block 215, in which a p-type photovoltaic layer is provided over the hole blocking layer. In block 216, an anode contact structure is provided over the p-type photovoltaic layer.

FIG. 7H shows an example of a flow diagram illustrating a manufacturing process 220 for a photovoltaic device including a hole blocking layer. The illustrated process 220 starts at block 222, in which a cathode contact structure is provided over a substrate. The process 220 continues at block 223, in which a hole blocking layer is provided over the cathode contact structure. In a block 224, an n-type photovoltaic layer is provided over the cathode contact structure. The process 220 continues at block 225, in which a p-type photovoltaic layer is provided over the n-type photovoltaic layer. In block 226, an anode contact structure is provided over the p-type photovoltaic layer.

FIGS. 8A-8B show examples of flow diagrams illustrating various manufacturing processes for photovoltaic devices including a minority carrier blocking layer.

FIG. 8A shows an example of a flow diagram illustrating a manufacturing process 250 for a photovoltaic device including a hole blocking layer. The process 250 starts at 251. In block 252, an anode contact structure is provided. In certain implementations, the anode contact structure is a TCO structure. However, in other implementations the anode contact structure can include nickel (Ni), aluminum (Al), Au, and/or Mo.

The process 250 continues at a block 253, in which a cathode contact structure is provided. In certain implementations, the cathode contact structure is a TCO structure. In other implementations the cathode contact structure includes Ni, Al, Au, and/or Mo.

In an ensuing block 254, a p-type photovoltaic layer is provided adjacent the anode contact structure. In certain implementations, the p-type photovoltaic layer includes at least one of a-Si, copper indium gallium selenide (CuInₓGa₁₋ₓSe₂), and CdTe. In the block 255, an n-type photovoltaic layer is provided between the cathode contact structure and the p-type photovoltaic layer. The n-type photovoltaic layer can be, for example, CdS or n-type amorphous silicon.

The process 250 continues at a block 256, in which a hole blocking layer is provided between the p-type photovoltaic layer and the cathode contact structure. The p-type photovoltaic layer, the n-type photovoltaic layer, and the hole blocking layer can collectively form an inorganic solar cell. The hole blocking layer can provide an energy barrier to holes in the p-type photovoltaic layer from reaching an interface between the inorganic solar cell and the cathode contact structure provided in block 253. In some implementations, after block 256 other subsequent steps may also be performed.

FIG. 8B shows an example of a flow diagram illustrating a manufacturing process 260 for a photovoltaic device including an electron blocking layer. The process 260 starts at block 262, in which an anode contact structure is provided. The process 260 continues at a block 263, in which a cathode contact structure is provided. In an ensuing block 264, a p-type photovoltaic layer is provided adjacent the anode contact structure. The process 260 continues at a block 265, in which an n-type photovoltaic layer is provided between the cathode contact structure and the p-type photovoltaic layer. The blocks 262-265 of FIG. 8B can be similar to the blocks 252-255 of FIG. 8A described above.

The process 260 continues at a block 266, in which an electron blocking layer is provided between the n-type photovoltaic layer and the anode contact structure. The p-type photovoltaic layer, the n-type photovoltaic layer, and the electron blocking layer can collectively form an inorganic solar cell. The electron blocking layer can provide an energy barrier to electrons in the n-type photovoltaic layer from reaching an interface between the inorganic solar cell and the anode contact structure provided in block 263. By providing a barrier for electrons in this manner, recombination of holes at the interface can be decreased. In certain implementations, the electron blocking layer can include a material having a relatively high optical transparency, a relatively low defect density, and a relatively high hole carrier concentration.

The method is illustrated as ending at 266, however, other subsequent steps may also be performed. Additionally, in certain implementations, the methods of FIGS. 8A and 8B can be combined to form a photovoltaic device with both an electron blocking layer and a hole blocking layer.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that any described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A photovoltaic device comprising:
an anode contact structure;
a cathode contact structure; and
an inorganic solar cell disposed between the anode and cathode contact structures, the inorganic solar cell including
a p-type photovoltaic layer adjacent the anode contact structure,
an n-type photovoltaic layer disposed between the cathode contact structure and the p-type photovoltaic layer, and
a hole blocking layer also disposed between the cathode contact structure and the p-type photovoltaic layer, wherein the hole blocking layer provides an energy barrier to holes that is more than an energy barrier provided to electrons.

2. The photovoltaic device of claim 1, wherein a boundary between the cathode contact structure and the inorganic solar cell defines a first interface surface, and wherein the hole blocking layer prevents holes in the p-type photovoltaic layer from reaching the first interface surface and permits electrons to cross when the inorganic solar cell is generating current.

3. The photovoltaic device of claim 2, further comprising an electron blocking layer disposed between the n-type photovoltaic layer and the anode contact structure, wherein a boundary between the anode contact structure and the inorganic solar cell defines a second interface surface, and wherein the electron blocking layer prevents electrons in the n-type photovoltaic layer from reaching the second interface surface and permits holes to cross when the inorganic solar cell is generating current.

4. The photovoltaic device of claim 1, wherein the hole blocking layer has a band gap that is about 0.2 eV to about 1.0 eV greater than a band gap of the p-type photovoltaic layer.

5. The photovoltaic device of claim 1, wherein the hole blocking layer has a thickness ranging between about 1 nm and about 10 nm.

6. The photovoltaic device of claim 1, wherein the hole blocking layer is disposed between the p-type and n-type photovoltaic layers.

7. The photovoltaic device of claim 1, wherein the n-type photovoltaic layer includes n-type amorphous silicon and the p-type photovoltaic layer includes p-type amorphous silicon, and wherein the inorganic solar cell further includes an intrinsic amorphous silicon layer disposed between the p-type and n-type photovoltaic layers, and wherein the hole blocking layer includes n-type amorphous silicon having a band gap that is about 0.05 eV to about 0.15 eV greater than a band gap of the n-type photovoltaic layer.

8. The photovoltaic device of claim 7, further comprising a transparent substrate adjacent the anode contact structure on a side of the anode contact structure opposite the inorganic solar cell, and wherein the anode contact structure includes a transparent conductive oxide layer, the inorganic solar cell configured to receive light through the transparent substrate and the transparent conductive oxide.

9. The photovoltaic device of claim 1, wherein the n-type photovoltaic layer includes cadmium sulfide (CdS) and the p-type photovoltaic layer includes cadmium telluride (CdTe), and wherein the hole blocking layer includes at least one of zinc selenide (ZnSe), an alloy of cadmium oxide and zinc oxide in a ratio of x and 1-x (CdₓZn₁₋ₓO), an alloy of cadmium sulfide and zinc sulfide in a ratio of x and 1-x (CdₓZn₁₋ₓS), indium sulfide (In₂S₃), and zinc oxysulfide in a ratio of x and 1-x (ZnOₓS₁₋ₓ).

10. The photovoltaic device of claim 9, further comprising a transparent substrate adjacent the cathode contact structure on a side of the cathode contact structure opposite the inorganic solar cell, and wherein the cathode contact structure includes a transparent conductive oxide layer, the inorganic solar cell configured to receive light through the transparent substrate and the transparent conductive oxide.

11. The photovoltaic device of claim 1, wherein the n-type photovoltaic layer includes cadmium sulfide (CdS) and the p-type photovoltaic layer includes copper indium gallium selenide (CuInₓGa₁₋ₓSe₂), and wherein the hole blocking layer includes at least one of zinc selenide (ZnSe), an alloy of cadmium oxide and zinc oxide in a ratio of x and 1-x (CdₓZn₁₋ₓO), an alloy of cadmium sulfide and zinc sulfide in a ratio of x and 1-x (CdₓZn₁₋ₓS), indium sulfide (In₂S₃), and zinc oxysulfide in a ratio of x and 1-x (ZnOₓS₁₋ₓ).

12. The photovoltaic device of claim 11, further comprising a substrate adjacent the anode contact structure on a side of the anode contact structure opposite the inorganic solar cell, and wherein the cathode contact structure includes a transparent conductive oxide layer, the inorganic solar cell configured to receive light through the transparent conductive oxide.

13. A method of forming a thin film solar cell device, the method comprising:
providing an anode contact structure;
providing an inorganic solar cell adjacent the anode contact structure;
providing a cathode contact structure adjacent the inorganic solar cell on a side of the inorganic solar cell opposite the anode contact structure, and
wherein providing the inorganic solar cell includes:
providing a p-type photovoltaic layer adjacent the anode contact structure,
providing an n-type photovoltaic layer between the cathode contact structure and the p-type photovoltaic layer, and
providing a hole blocking layer between the cathode contact structure and the p-type photovoltaic layer, wherein the hole blocking layer provides an energy barrier to holes that is more than an energy barrier provided to electrons.

14. The method of claim 13, wherein a boundary between the cathode contact structure and the inorganic solar cell defines a first interface surface, and wherein the hole blocking layer prevents holes in the p-type photovoltaic layer from reaching the first interface surface and permits electrons to cross when the inorganic solar cell is generating current.

15. The method of claim 13, wherein forming the hole blocking layer includes forming the hole blocking layer between the p-type and n-type photovoltaic layers.

16. The method of claim 13, further comprising forming an intrinsic amorphous silicon layer between the p-type and n-type photovoltaic layers, wherein the n-type photovoltaic layer includes n-type amorphous silicon and the p-type photovoltaic layer includes p-type amorphous silicon, and wherein the hole blocking layer includes n-type amorphous silicon having a band gap that is about 0.05 eV to about 0.15 eV greater than a band gap of the n-type photovoltaic layer.

17. A photovoltaic device comprising:
an anode contact structure;
a cathode contact structure; and
an inorganic solar cell disposed between the anode and cathode contact structures, the inorganic solar cell including
a p-type photovoltaic layer adjacent the anode contact structure,
an n-type photovoltaic layer disposed between the cathode contact structure and the p-type photovoltaic layer, and
a means for blocking holes disposed between the cathode contact structure and the p-type photovoltaic layer, wherein the hole blocking means provides an energy barrier to holes that is more than an energy barrier provided to electrons.

18. A photovoltaic device comprising:
an anode contact structure;
a cathode contact structure; and
an inorganic solar cell disposed between the anode and cathode contact structures, the inorganic solar cell including
an n-type photovoltaic layer adjacent the cathode contact structure,
a p-type photovoltaic layer disposed between the anode contact structure and the n-type photovoltaic layer, and
an electron blocking layer also disposed between the anode contact structure and the n-type photovoltaic layer, wherein the electron blocking layer provides an energy barrier to electrons that is more than an energy barrier provided to holes.

19. The photovoltaic device of claim 18, wherein a boundary between the anode contact structure and the inorganic solar cell defines a first interface surface, and wherein the electron blocking layer prevents electrons in the n-type photovoltaic layer from reaching the first interface surface and permits holes to cross when the inorganic solar cell is generating current.

20. The photovoltaic device of claim 19, further comprising a hole blocking layer disposed between the p-type photovoltaic layer and the cathode contact structure, wherein a boundary between the cathode contact structure and the inorganic solar cell defines a second interface surface, and wherein the hole blocking layer prevents holes in the p-type photovoltaic layer from reaching the second interface surface and permits electrons to cross when the inorganic solar cell is generating current.

21. The photovoltaic device of claim 18, wherein the electron blocking layer has a band gap that is about 0.2 eV to about 1.0 eV greater than a band gap of the n-type photovoltaic layer.

22. The photovoltaic device of claim 18, wherein the electron blocking layer has a thickness ranging between about 1 nm and about 10 nm.

23. The photovoltaic device of claim 18, wherein the electron blocking layer is disposed between the p-type and n-type photovoltaic layers.

24. The photovoltaic device of claim 18, wherein the n-type photovoltaic layer includes n-type amorphous silicon and the p-type photovoltaic layer includes p-type amorphous silicon, and wherein the inorganic solar cell further includes an intrinsic amorphous silicon layer disposed between the p-type and n-type photovoltaic layers, and wherein the electron blocking layer includes p-type amorphous silicon having a band gap that is about 0.05 eV to about 0.15 eV greater than a band gap of the p-type photovoltaic layer.

25. The photovoltaic device of claim 24, further comprising a transparent substrate adjacent the anode contact structure on a side of the anode contact structure opposite the inorganic solar cell, and wherein the anode contact structure includes a transparent conductive oxide layer, the inorganic solar cell configured to receive light through the transparent substrate and the transparent conductive oxide.

26. The photovoltaic device of claim 18, wherein the n-type photovoltaic layer includes cadmium sulfide (CdS) and the p-type photovoltaic layer includes cadmium telluride (CdTe), and wherein the electron blocking layer includes at least one of zinc selenide (ZnSe), an alloy of cadmium telluride and zinc telluride in a ratio of x and 1-x (CdₓZn₁₋ₓTe), an alloy of cadmium selenide and zinc selenide in a ratio of x and 1-x (CdₓZn₁₋ₓSe), an alloy of cadmium sulfide and cadmium telluride in a ratio of x and 1-x (CdTe₁₋ₓSₓ), an alloy of cadmium selenide and cadmium telluride in a ratio of x and 1-x (CdTe₁₋ₓSeₓ), an alloy of cadmium selenide and cadmium sulfide in a ratio of 1-x and x (CdSe₁₋ₓSₓ), an alloy of mercury sulfide and mercury telluride in a ratio of x and 1-x (HgTe₁₋ₓSₓ), and an alloy of mercury selenide and mercury sulfide in a ratio of 1-x and x (HgSe₁₋ₓSₓ).

27. The photovoltaic device of claim 26, further comprising a transparent substrate adjacent the cathode contact structure on a side of the cathode contact structure opposite the inorganic solar cell, and wherein the cathode contact structure includes a transparent conductive oxide layer, the inorganic solar cell configured to receive light through the transparent substrate and the transparent conductive oxide.

28. The photovoltaic device of claim 18, wherein the n-type photovoltaic layer includes cadmium sulfide (CdS) and the p-type photovoltaic layer includes copper indium gallium selenide (CuInₓGa₁₋ₓSe₂), and wherein the hole blocking layer includes at least one of zinc selenide (ZnSe), an alloy of cadmium telluride and zinc telluride in a ratio of x and 1-x (CdₓZn₁₋ₓTe), an alloy of cadmium selenide and zinc selenide in a ratio of x and 1-x (CdₓZn₁₋ₓSe), an alloy of cadmium sulfide and cadmium telluride in a ratio of x and 1-x (CdTe₁₋ₓSₓ), an alloy of cadmium selenide and cadmium telluride in a ratio of x and 1-x (CdTe₁₋ₓSeₓ), an alloy of cadmium selenide and cadmium sulfide in a ratio of 1-x and x (CdSe₁₋ₓSₓ), an alloy of mercury sulfide and mercury telluride in a ratio of x and 1-x (HgTe₁₋ₓSₓ), and an alloy of mercury selenide and mercury sulfide in a ratio of 1-x and x (HgSe₁₋ₓSₓ).

29. The photovoltaic device of claim 28, further comprising a substrate adjacent the anode contact structure on a side of the anode contact structure opposite the inorganic solar cell, and wherein the cathode contact structure includes a transparent conductive oxide layer, the inorganic solar cell configured to receive light through the transparent conductive oxide.

30. A method of forming a thin film solar cell device, the method comprising:
providing a cathode contact structure;
providing an inorganic solar cell adjacent the cathode contact structure;
providing an anode contact structure adjacent the inorganic solar cell on a side of the inorganic solar cell opposite the cathode contact structure, and
wherein providing the inorganic solar cell includes:
providing an n-type photovoltaic layer adjacent the cathode contact structure,
providing a p-type photovoltaic layer between the anode contact structure and the n-type photovoltaic layer, and
providing an electron blocking layer between the anode contact structure and the n-type photovoltaic layer, wherein the electron blocking layer provides an energy barrier to electrons that is more than an energy barrier provided to holes.

31. The method of claim 30, wherein a boundary between the anode contact structure and the inorganic solar cell defines a first interface surface, and wherein the electron blocking layer prevents electrons in the n-type photovoltaic layer from reaching the first interface surface and permits holes to cross when the inorganic solar cell is generating current.

32. The method of claim 30, wherein forming the electron blocking layer includes forming the electron blocking layer between the p-type and n-type photovoltaic layers.

33. The method of claim 30, further comprising forming an intrinsic amorphous silicon layer between the p-type and n-type photovoltaic layers, wherein the n-type photovoltaic layer includes n-type amorphous silicon and the p-type photovoltaic layer includes p-type amorphous silicon, and wherein the electron blocking layer includes p-type amorphous silicon having a band gap that is about 0.05 eV to about 0.15 eV greater than a band gap of the p-type photovoltaic layer.

34. A photovoltaic device comprising:
an anode contact structure;
a cathode contact structure; and
an inorganic solar cell disposed between the anode and cathode contact structures, the inorganic solar cell including
an n-type photovoltaic layer adjacent the cathode contact structure,
a p-type photovoltaic layer disposed between the anode contact structure and the n-type photovoltaic layer, and
a means for blocking electrons disposed between the anode contact structure and the n-type photovoltaic layer, wherein the electron blocking means provides an energy barrier to electrons that is more than an energy barrier provided to holes.
